(19) United States
(12) Patent Application Publication
(10) Pub. No.: US 2026/0053056 A1
(43) Pub. Date: Feb. 19, 2026

(54) HOUSING AND SEMICONDUCTOR MODULE HAVING A HOUSING

(71) Applicant: Infineon Technologies AG, Neubiberg (DE)

(72) Inventors: Alexander Schmer, Soest (DE); Thomas Herbst, Arnsberg (DE); Niklas Keller, Eslohe (DE)

(21) Appl. No.: 19/296,212

(22) Filed: Aug. 11, 2025

(30) Foreign Application Priority Data
Aug. 19, 2024 (DE) 102024123645.0

(51) Int. Cl. H01L 23/053; H01L 21/48; H01L 23/00; H01L 23/043; H01L 23/373; H01L 25/07

(52) U.S. Cl. CPC H01L 23/053; H01L 21/4803; H01L 23/043; H01L 23/3735; H01L 24/32; H01L 24/48; H01L 24/73; H01L 25/072; H01L 2224/32225; H01L 2224/48225; H01L 2224/73265

(57) ABSTRACT

A housing for a semiconductor module includes sidewalls extending horizontally around an internal volume of the housing and a groove formed in a bottom surface of the sidewalls and extending along a circumference of the housing. The bottom surface of the sidewalls is configured to be attached to a substrate or a base plate. The groove extends into the sidewalls of the housing in a vertical direction. The groove includes a first section having a constant width in a horizontal direction and beveled edges between the first section and the bottom surface of the sidewalls. The beveled edges define a second section arranged between the first section and the bottom surface of the sidewalls, and having a varying width in the horizontal direction. The width of the second section gradually increases from the first section towards the bottom surface of the sidewalls.

### TECHNICAL FIELD

The instant disclosure relates to a housing, and a semiconductor module comprising a housing.

### BACKGROUND

Power semiconductor module arrangements often include at least one substrate arranged in a housing. A semiconductor arrangement including a plurality of controllable semiconductor elements (e.g., two IGBTs in a half-bridge configuration) or non-controllable semiconductor elements (e.g., arrangements of diodes) is arranged on each of the at least one substrate. Each substrate usually comprises a substrate layer (e.g., a ceramic layer), a first metallization layer deposited on a first side of the substrate layer and (optionally) a second metallization layer deposited on a second side of the substrate layer. The controllable semiconductor elements are mounted, for example, on the first metallization layer. The housing may be glued to the substrate such that the substrate forms a ground surface of the housing. When gluing the substrate to the housing, it needs to be ensured that sufficient glue is provided in order to provide a stable connection between the substrate and the housing and to seal a gap between the housing and the substrate. On the other hand, if too much glue is applied to the substrate or the housing, there is a risk that excessive glue is pressed out of the housing towards a bottom side of the semiconductor module, which is generally undesirable because it can interfere with the interface between the substrate and a heat sink to which the module will be attached.

There is a need for a housing for a semiconductor module arrangement that may be securely glued to a substrate.

### SUMMARY

A housing for a semiconductor module according to embodiments of the disclosure includes sidewalls, the sidewalls extending horizontally around an internal volume of the housing, wherein the housing includes a groove formed in a bottom surface of the sidewalls and extending along a circumference of the housing, wherein the bottom surface of the sidewalls is configured to be attached to a substrate or a base plate, the groove extends into the sidewalls of the housing in a vertical direction, the groove includes a first section having a constant width in a horizontal direction, and the groove includes beveled edges between the first section and the bottom surface of the sidewalls, the beveled edges defining a second section arranged between the first section and the bottom surface of the sidewalls, and having a varying width in the horizontal direction, wherein the width of the second section gradually increases from the first section towards the bottom surface of the sidewalls.

A semiconductor module according to embodiments of the disclosure includes the housing, a substrate or base plate, and a glued joint. The glued joint is arranged in the groove, wherein a surface of the glued joint facing towards the outside of the groove is flush with the bottom surface of the sidewalls. The substrate or base plate contacts the bottom surface of the sidewalls and the surface of the glued joint facing towards the outside of the groove.

A method for assembling a semiconductor module according to embodiments of the disclosure includes forming a glue bead on the beveled edges of the groove of the housing, arranging the housing on a substrate or base plate, wherein arranging the housing on the substrate or base plate includes pressing the housing on the substrate or base plate until the substrate or base plate contacts the bottom surface of the housing, thereby pressing the glue bead into the groove.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a semiconductor module in which the housing is glued to a substrate.

FIGS. 2A and 2B illustrate cross-sectional views of sections of substrates glued to a sidewall of a conventional housing.

FIG. 3 is a cross-sectional view of a section of a housing according to embodiments of the disclosure.

FIG. 4 schematically illustrates exemplary dimensions of a groove formed in a housing according to embodiments of the disclosure.

FIG. 5 schematically illustrates a cross-sectional view of a section of a substrate glued to a housing according to embodiments of the disclosure.

FIG. 6 schematically illustrates a cross-sectional view of a section of a substrate glued to a housing according to embodiments of the disclosure.

FIG. 7 schematically illustrates a three-dimensional view of a section of a housing according to embodiments of the disclosure.

FIG. 8 schematically illustrates a bottom view of a housing according to embodiments of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description, as well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable). A semiconductor body as described herein may be made from (doped) semiconductor material and may be a semiconductor chip or be included in a semiconductor chip. A semiconductor body has electrically connecting pads and includes at least one semiconductor element with electrodes.

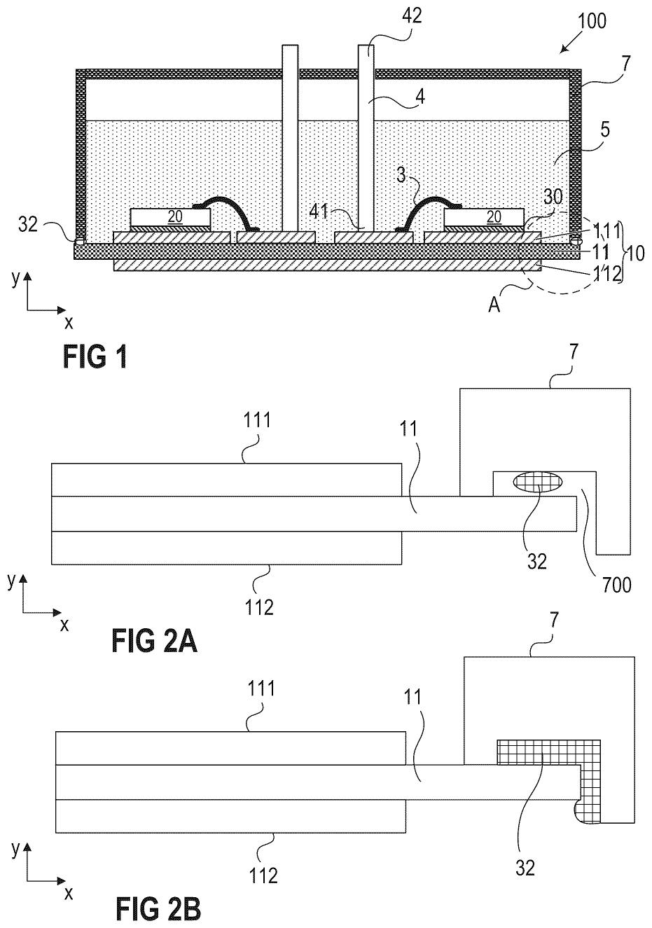

Referring to FIG. 1, a cross-sectional view of a semiconductor module 100 is illustrated. The semiconductor module 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 11 may consist of or include one of the following materials: Al₂O₃, AlN, SiC, BeO or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, or BN and may have a diameter of between about 1 μm and about 50 μm. The substrate 10 may also be a conventional printed circuit board (PCB) having a non-ceramic dielectric insulation layer 11. For instance, a non-ceramic dielectric insulation layer 11 may consist of or include a cured resin.

The substrate 10 may be arranged in a housing 7. In the example illustrated in FIG. 1, the substrate 10 itself forms a base surface of the housing 7, while the housing 7 itself solely comprises sidewalls and a cover. Such semiconductor modules are often referred to as base plate less modules. The cover of the housing 7 is generally optional and may also be omitted.

One or more semiconductor bodies 20 may be arranged on the substrate 10. Each of the semiconductor bodies 20 arranged on the substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable controllable or non-controllable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. The first metallization layer 111 is a structured layer in the example illustrated in FIG. 1. “Structured layer” means that the first metallization layer 111 is not a continuous layer, but includes recesses between different sections of the layer. Such recesses are schematically illustrated in FIG. 1. The first metallization layer 111 in this example includes four different sections. Different semiconductor bodies 20 may be mounted to the same or to different sections of the first metallization layer 111. Different sections of the first metallization layer may have no electrical connection or may be electrically connected to one or more other sections using, e.g., bonding wires 3. Electrical connections 3 may also include connection plates or conductor rails, for example, to name just a few examples. The one or more semiconductor bodies 20 may be electrically and mechanically connected to the substrate 10 by an electrically conductive connection layer 30. Such an electrically conductive connection layer may be a solder layer, a layer of an electrically conductive adhesive, or a layer of a sintered metal powder, e.g., a sintered silver powder, for example.

The semiconductor module 100 illustrated in FIG. 1 further includes terminal elements 4. The terminal elements 4 are electrically connected to the first metallization layer 111 and provide an electrical connection between the inside and the outside of the housing 7. The terminal elements 4 may be electrically connected to the first metallization layer 111 with a first end 41, while a second end 42 of the terminal elements 4 protrudes out of the housing 7. The terminal elements 4 may be electrically contacted from the outside at their second end 42. The terminal elements 4 illustrated in FIG. 1, however, are only examples. Terminal elements 4 may be implemented in any other way and may be arranged at any other position. For example, one or more terminal elements 4 may be arranged close to or adjacent to the sidewalls of the housing 7. Any other suitable implementation is possible. The terminal elements 4 may consist of or include a metal such as copper, aluminum, gold, silver, or any alloys thereof, for example. The terminal elements 4 may be electrically and mechanically connected to the substrate 10 by an electrically conductive connection layer (not specifically illustrated for the terminal elements 4). Such an electrically conductive connection layer generally may be a solder layer, a layer of an electrically conductive adhesive, or a layer of a sintered metal powder, e.g., a sintered silver powder, for example. According to other examples, terminal elements 4 may be inserted into hollow sleeves which are attached to the substrate 10 (sleeves not specifically illustrated in FIG. 1).

Conventional semiconductor modules 100 generally further include an encapsulant or casting compound 5. The casting compound 5 may consist of or include a cured silicone gel or may be a rigid molding compound, for example. The casting compound 5 may at least partly fill the interior of the housing 7, thereby covering the components and electrical connections that are arranged on the substrate 10. The terminal elements 4 may be partly embedded in the casting compound 5. At least their second ends 42, however, are not covered by the casting compound 5 and protrude from the casting compound 5 through the housing 7, to the outside of the housing 7. The casting compound 5 is configured to protect the components and electrical connections inside the semiconductor module 100, in particular inside the housing 7, from certain environmental conditions and mechanical damage.

In the example illustrated in FIG. 1, the housing 7 is arranged on the substrate 10 such that the substrate 10 forms a bottom of the housing 7. In such semiconductor modules which are often also referred to as base plate less modules, the housing 7 is usually glued to the substrate 10 in order to remain in a desired position with respect to the substrate 10. A glued joint 32 (layer of glue) between the housing 7 and the substrate 10 is often sufficient to hold the housing 7 in its desired position with respect to the substrate 10. The glued joint 32 further seals the housing 7 such that the material that is used to form the casting compound 5 does not leak out of the housing 7 before it is sufficiently hardened (cured).

Conventional housings 7 often comprise a broad depression or recess 700 in a bottom side of the sidewalls of the housing 7, as is schematically illustrated in FIGS. 2A and 2B. FIGS. 2A and 2B schematically illustrate cross-sectional views of a section A of a semiconductor module as indicated in FIG. 1. The bottom side of the sidewalls is a side that, in the assembled state of the semiconductor module, is attached to the substrate 10. The glue 32 that is used to attach the housing 7 to the substrate 10 is arranged in the depression or recess 700. There is generally a risk that, if a too small amount of glue 32 is applied to the housing 7 (i.e. in the depression or recess 700), the connection between the housing 7 and the substrate 10 is not strong enough to sufficiently attach the housing 7 to the substrate 10. This is, because if a too small amount of glue 32 is applied, the glue 32 may not sufficiently project from the depression or recess 700 such that it does not even reach the substrate 10 at all, or such that only a very small contact surface is formed between the glue 32 and the substrate 10, when the housing 7 is arranged on the substrate 10. This is schematically illustrated in FIG. 2A. In this case, there is also the risk that material that is used to form the casting compound 5 leaks out of the housing 7, as a gap between the housing 7 and the substrate 10 may not be sufficiently sealed along the entire circumference of the housing 7. If, on the other hand, too much glue 32 is applied to the housing 7, there is a risk that a certain amount of glue 32 is pressed out of the depression or recess, when the housing 7 is arranged on the substrate 10. This is schematically illustrated in FIG. 2B. Applying the glue 32 to the housing 7 is generally subject to certain tolerances. Therefore, applying the correct amount of glue 32 may not always be possible.

A housing 7 according to embodiments of the disclosure comprises sidewalls, the sidewalls extending horizontally around an internal volume of the housing 7. The housing 7 further comprises a groove 702 formed in a bottom surface of the sidewalls and extending along a circumference of the housing 7, wherein the bottom surface of the sidewalls is configured to be attached to a substrate 10. The groove 702 extends from the bottom surface into the sidewalls of the housing 7 in a vertical direction y, and comprises a first section 702a having a constant width w702a in a horizontal direction, and further comprises beveled edges 704 between the first section 702a and the bottom surface of the sidewalls, the beveled edges 704 defining a second section 702b arranged between the first section 702a and the bottom surface of the sidewalls, and having a varying width w702b in the horizontal direction, wherein the width w702b of the second section 702b gradually increases from the first section 702a towards the bottom surface of the sidewalls.

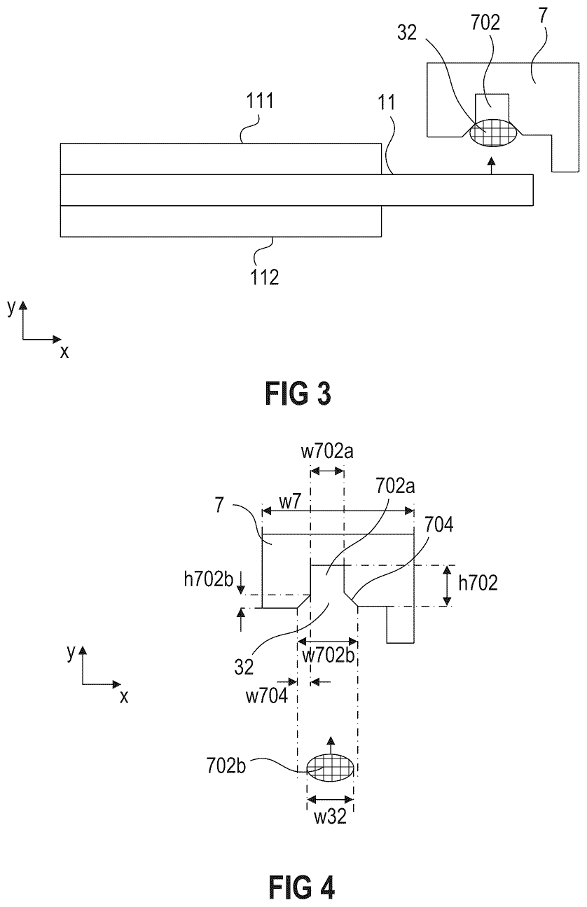

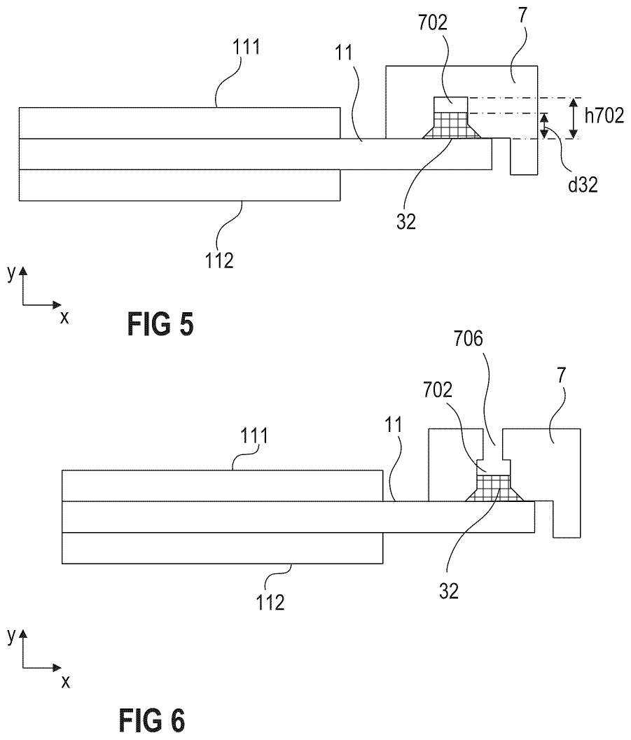

The beveled edges 704 provide supporting surfaces for a glue bead 32 that is applied to the housing 7 in order to attach the housing 7 to the substrate 10. This is schematically illustrated in FIG. 3, which schematically illustrates a cross-sectional view of a section A of a semiconductor module as indicated in FIG. 1. The glue bead 32 rests on the beveled edges 704 of the groove 702 before the housing 7 is arranged on the substrate 10. When the housing 7 is arranged on the substrate 10, the glue 32 is pressed into the first section 702a of the groove 702, as is schematically illustrated in FIG. 5. FIG. 5 schematically illustrates a cross-sectional view of a section A of a semiconductor module as indicated in FIG. 1. When the housing 7 is in its final mounting position on the substrate 10, the glued joint 32 extends from the bottom surface of the sidewalls into the groove 702 in the vertical direction (y), wherein a maximum thickness d32 of the glued joint 32 in the vertical direction y is less than a depth h702 of the groove 702 in the same direction. That is, not the entire groove 702 is filled with glue 32.

A glue 32 that is used to attach a housing 7 to a substrate 10 generally has a certain viscosity, and does not, or at least not significantly, flow further into the groove 702 by itself. It is only further pressed into the groove 702 when the housing 7 is pressed on the substrate 10. When the housing 7 is pressed onto the substrate 10, pressure is also exerted on the glue 32. The beveled edges 704 guide the glue 32 towards the first section 702a, which provides a reservoir for any excess glue 32. The second section 702b defined by the beveled edges 704 is comparably flat. That is, the supporting surfaces to which the glue 32 is applied are comparably close to the bottom surface of the sidewalls. The risk of a substrate 10 not getting into contact with the glue 32 at all or of a too small contact surface forming between the substrate 10 and the glue 32, therefore, is significantly reduced. If only a small amount of glue 32 is applied, the substrate 10 will still contact the glue 32 and a stable connection between the housing 7 and the substrate 10 will be formed. If a large amount of glue 32 is applied, a stable connection between the housing 7 and the substrate 10 will also be formed, and any excess glue 32 will be pressed into the first section 702a of the groove 702, when the housing 7 is pressed on the substrate 10. Any disadvantages that have been described with respect to conventional housings 7 above, therefore, are overcome. The groove 702 as described with respect to FIG. 3 further provides a greater contact surface between the glue 32 and the housing 7, which further increases adhesion between the housing 7 and the substrate 10.

Now referring to FIG. 4, exemplary dimensions of a groove 702 of a housing 7 according to embodiments of the disclosure are schematically illustrated. According to embodiments of the disclosure, the width w702a of the first section 702a may be between 0.6 and 0.8 mm. An overall depth h702 of the groove 702 in the vertical direction y may be at least 1.0 mm. A certain minimum depth h702 of the groove 702 is generally required in order to provide a large enough reservoir for any excess glue 32. A greater depth h702 on the other hand is generally not disadvantageous, as the glue 32 will only be pressed into the groove 702 until the substrate 10 contacts the bottom surface of the housing 7. That is, a groove 702 may not be entirely filled with glue 32 when the semiconductor module is completely assembled. Portions of the groove 702 (i.e. of the first section 702a) may remain free of glue 32. This does not affect the overall function of the semiconductor module in any way. A depth h702b of the second section 702b in the vertical direction y may be between 0.1- 0.3 mm, for example. A maximum width w702b of the second section 702b at the bottom surface of the sidewalls may be between 1.1 and 1.3 mm. This results in a contact surface between the glue 32 and the substrate 10 that is sufficiently large in order to securely attach the housing 7 to the substrate 10.

A difference between the width w702a of the first section 702a and the maximum width w702b of the second section 702b at the bottom surface of the housing 7 may be between 0.1 and 0.3 mm. That is, the beveled edges 704 may extend from the sidewalls of the groove 702 towards the bottom surface of the sidewalls of the housing 7 with an angle of between 20° and 70°. This angle may be identical for both beveled edges 704 of the groove 702. It is, however, generally also possible that one of the two beveled edges 704 is steeper than the other. For example, the beveled edge 704 which is closer to the internal volume of the housing 7 may be steeper than the beveled edge which is further away from the internal volume, or vice versa. The width w702a of the first section 702a is defined by a distance between the opposite sidewalls of the groove 702. A width w32 of the glue bead 32 applied to the groove 702 may be equal to or less than the maximum width w702b of the second section 702b at the bottom surface of the sidewalls. That is, according to some examples, the width w32 of the glue bead 32 may be equal to or less than 1.1 and 1.3 mm. In this way, the glue 32 will be entirely pressed into the groove 702, and any glue being pressed out of the groove 702 and between the bottom surface of the housing 7 and the substrate 10 is avoided.

As is schematically illustrated in FIG. 8, the groove 702 may extend along the entire circumference of the housing 7. In this way, the housing 7 may be securely attached to the substrate 10, and a gap between the housing 7 and the substrate 10 may be completely sealed by means of a glue bead 32 formed in the groove 702 along the entire circumference of the housing 7. The dimensions of the groove 702 may be constant along the entire circumference of the housing 7. It is, however, also possible that the groove 702 comprises different segments along the circumference of the housing 7, and that at least one of the dimensions of a segment differs from the dimensions of one or more of the other segments. For example, the groove 702 may have a different depth h702 in different segments. Additionally or alternatively, the dimensions of the second section 702b as defined by the beveled edges 704 may differ for different segments of the groove 702. For example, the beveled edges 704 may be steeper in some sections, and flatter in others. According to one example, the groove 702 may have a first number of segments of a first kind, and a second number of segments of a second kind, the segments of the first kind and the segments of the second kind being arranged alternatingly along the circumference of the housing 7. At least one of the dimensions of the segments of the first kind may differ from the respective dimension of the segments of the second kind. It is also possible that there are even more than two different kinds of segments.

If a glue bead 32 is arranged on the groove 702 along the entire circumference of the housing 7, and the glue 32 is then pressed further into the groove 702 when mounting the housing 7 on the substrate 10, there may be no way for air to escape from the groove 702 (i.e. from the first section 702a). Therefore, the housing 7 may further comprise at least one ventilation hole 706 extending from the groove 702 through the housing 7 to the outside of the housing 7. This is schematically illustrated in FIG. 6, which schematically illustrates a cross-sectional view of a section A of a semiconductor module as indicated in FIG. 1. Each ventilation hole 706 of the at least one ventilation hole 706 provides an opening from the first section 702a of the groove 702 towards outside air. In this way, when the glue 32 is pressed into the groove 702 along the entire circumference of the housing 7, air may escape from the first section 702a of the groove 702. The number of ventilation holes 706 generally depends on the dimensions of the housing 7 and the groove 702. In some cases, a single (exactly one) ventilation hole 706 may be sufficient. In other cases, more than one ventilation hole 706 may be required. In the example illustrated in FIG. 6, the ventilation hole 706 extends from the groove 702 in the vertical direction y through the housing 7. This, however, is only an example. It is generally also possible that a ventilation hole 706 extends horizontally from the groove 702 to the outside of the housing 7. It is also possible that a ventilation hole 706 comprises vertical as well as horizontal sections. Even diagonal sections are generally possible. An opening of the ventilation hole 706 may be arranged at an end of the groove 702 which faces away from the bottom surface of the housing 7. In this way, it can be ensured that the opening of the ventilation hole 706 does not get blocked by glue 32 and air may freely escape from the groove 702.

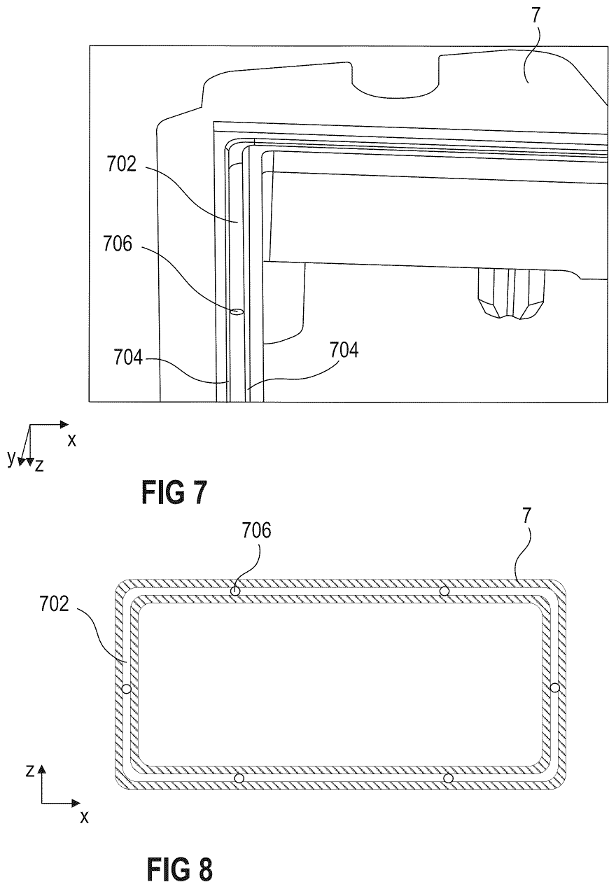

FIG. 7 schematically illustrates a three-dimensional bottom view of a section of a housing 7 according to embodiments of the disclosure. In this view, one ventilation hole 706 is visible. The housing 7 illustrated in the bottom view of FIG. 8 comprises a total of six ventilation holes 706, arranged at different positions along the groove 702. According to one example, a housing 7 comprises at least one ventilation hole 706 in each sidewall of the housing 7. It is also possible that one ventilation hole 706 is arranged in each of a plurality of corners of a housing 7. According to one example, ventilation holes 706 are arranged in regular intervals along the circumference of the housing 7.

Ventilation holes 706 may have a round cross-section as is schematically illustrated in FIGS. 7 and 8. This, however, is only an example. Ventilation holes 706 may generally have any suitable cross-section such as, e.g., oval, square, triangular, polygonal, etc. A round ventilation hole 706 may have a diameter which corresponds to or is smaller than the width w702a of the first section 702a of the groove 702, for example. According to one example, a diameter of a round ventilation hole 706 may be between 0.1 and 0.8 mm.

In the different examples described above, a housing according to embodiments of the disclosure is attached to a substrate 10 of a base plate less semiconductor module. In semiconductor modules comprising a base plate, the base plate generally forms a bottom of the housing 7 and one or more substrates 10 are arranged on the base plate and inside the housing 7. In a semiconductor module comprising a base plate, the housing may be glued to the base plate instead of to the substrate 10. The general principles as described above may similarly be applied to housings 7 that are attached to base plates. Such housings may have similar dimensions or may be somewhat larger as compared to housings 7 of base plate less semiconductor modules. The exemplary dimensions of the groove 702 as outlined above may be suitably adapted for larger housings 7. For example, a depth and a width of the first section 702a of the groove 702 may be the same or may be larger as compared to the exemplary dimensions presented above.

A semiconductor module 100 according to embodiments of the disclosure comprises a housing 7 as has been described above, a substrate 10 or base plate, and a glued joint 32. The glued joint 32 is arranged in the groove 702, wherein a surface of the glued joint 32 facing towards the outside of the groove 702 is flush with the bottom surface of the sidewalls. The substrate 10 or base plate contacts the bottom surface of the sidewalls and the surface of the glued joint 32 facing towards the outside of the groove 702. According to some embodiments, the glued joint 32 extends from the bottom surface of the sidewalls into the groove 702 in the vertical direction y, wherein a maximum thickness d32 of the glued joint 32 in the vertical direction y is less than a depth h702 of the groove 702 in the same direction.

A method for assembling a semiconductor module 100 according to embodiments of the disclosure comprises forming a glue bead 32 on the beveled edges 704 of the groove 702 of a housing 7 as has been described above, arranging the housing 7 on a substrate 10 or base plate, wherein arranging the housing 7 on the substrate 10 or base plate comprises pressing the housing 7 on the substrate 10 or base plate until the substrate 10 or base plate contacts the bottom surface of the housing 7, thereby pressing the glue bead 32 into the groove 702.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A housing for a semiconductor module, the housing comprising:
a plurality of sidewalls extending horizontally around an internal volume of the housing;
a groove formed in a bottom surface of the sidewalls and extending along a circumference of the housing,
wherein the bottom surface of the sidewalls is configured to be attached to a substrate or a base plate,
wherein the groove extends into the sidewalls of the housing in a vertical direction,
wherein the groove comprises a first section having a constant width in a horizontal direction,
wherein the groove further comprises a plurality of beveled edges between the first section and the bottom surface of the sidewalls, the beveled edges defining a second section arranged between the first section and the bottom surface of the sidewalls, and having a varying width in the horizontal direction,
wherein the width of the second section gradually increases from the first section towards the bottom surface of the sidewalls.

2. The housing of claim 1, wherein the width of the first section is between 0.6 and 0.8 mm.

3. The housing of claim 1, wherein a depth of the groove in the vertical direction is at least 1.0 mm.

4. The housing of claim 1, wherein a depth of the second section in the vertical direction is between 0.1 and 0.3 mm.

5. The housing of claim 1, wherein a maximum width of the second section at the bottom surface of the sidewalls is between 1.1 and 1.3 mm.

6. The housing of claim 5, wherein a difference between the width of the first section and the maximum width of the second section at the bottom surface of the housing is between 0.1 and 0.3 mm.

7. The housing of claim 1, further comprising at least one ventilation hole extending from the groove through the housing to an outside of the housing.

8. The housing of claim 7, further comprising at least one ventilation hole in each sidewall of the housing.

9. A semiconductor module, comprising:
the housing of claim 1;
a substrate or base plate; and
a glued joint arranged in the groove,
wherein a surface of the glued joint facing towards an outside of the groove is flush with the bottom surface of the sidewalls,
wherein the substrate or base plate contacts the bottom surface of the sidewalls and the surface of the glued joint facing towards the outside of the groove.

10. The semiconductor module of claim 9, wherein the glued joint extends from the bottom surface of the sidewalls into the groove in the vertical direction, and wherein a maximum thickness of the glued joint in the vertical direction is less than a depth of the groove in the same direction.

11. A method for assembling a semiconductor module, the method comprising:
forming a glue bead on a plurality of beveled edges of a groove of a housing, the housing further including a plurality of sidewalls extending horizontally around an internal volume of the housing, wherein the groove is formed in a bottom surface of the sidewalls and extends along a circumference of the housing into the sidewalls of the housing in a vertical direction, wherein the groove comprises a first section having a constant width in a horizontal direction, wherein the plurality of beveled edges is between the first section and the bottom surface of the sidewalls, the beveled edges defining a second section arranged between the first section and the bottom surface of the sidewalls, and having a varying width in the horizontal direction, wherein the width of the second section gradually increases from the first section towards the bottom surface of the sidewalls; and
pressing the housing on a substrate or base plate until the substrate or base plate contacts a bottom surface of the housing, thereby pressing the glue bead into the groove.
